(19) United States
(12) Patent Application Publication
(10) Pub. No.: US 2024/0113669 A1
(43) Pub. Date: Apr. 4, 2024

(54) EFFICIENCY IMPROVEMENTS FOR MULTI-STAGE POWER AMPLIFIERS

(71) Applicant: MACOM Technology Solutions Holdings, Inc., Lowell, MA (US)

(72) Inventors: Gerard J.L Bouisse, Toulouse (FR); Sullivan Yvon Claude Plet, Toulouse (FR); Carlo Poledrelli, Irvine, CA (US)

(21) Appl. No.: 17/766,611

(22) PCT Filed: Oct. 29, 2019
(86) PCT No.: PCT/IB2019/001234

§ 371 Date: Apr. 5, 2022

(51) Int. Cl. H03F 3/24; H01L 23/66; H03F 1/02; H03F 1/56; H03F 3/195

(52) U.S. Cl. CPC H03F 3/245; H01L 23/66; H03F 1/0288; H03F 1/565; H03F 3/195; H01L 2223/6611; H01L 2223/6655; H03F 2200/451

(57) ABSTRACT

Efficiency improvements for multi-stage power amplifiers are described. In one example, a power amplifier includes a driver amplifier formed on a first semiconductor die using a first semiconductor fabrication process, an output amplifier formed on a second semiconductor die using a second semiconductor fabrication process, and an inter-stage matching network formed between the driver amplifier and the output amplifier. The first semiconductor fabrication process is a lower voltage process and the second semiconductor fabrication process is a higher voltage process. The use of the two different fabrication processes leads to a number of advantages, including the simplification of the inter-stage matching network, increased radio frequency bandwidth, and improved line-up efficiency among the stages of the power amplifier.

### BACKGROUND

The semiconductor industry continues to see demands for integrated circuit (IC) devices having lower cost, size, and power consumption, particularly for monolithic microwave integrated circuit (MMIC) devices. MMIC devices include ICs designed for operation over microwave frequencies, such as in the 300 MHz to 300 GHz frequency range. MMIC devices can be relied upon for mixing, power amplification, low-noise amplification, and high-frequency switching operations, among others.

The efficiency of a power amplifier is driven by various factors, such as the intrinsic capability of the semiconductor materials used, the class and topology of the amplifier, and the harmonic tuning of the amplifier, among others. Some power amplifiers rely upon several cascaded stages of amplifiers to achieve a desired level of gain and radio frequency (RF) power. Among the cascaded stages, one or more driver stages of a power amplifier can provide an input signal to an output stage of the power amplifier.

### SUMMARY

Efficiency improvements for multi-stage power amplifiers are described herein. In one example, a power amplifier includes a driver amplifier formed on a first semiconductor die using a first semiconductor fabrication process, an output amplifier formed on a second semiconductor die using a second semiconductor fabrication process, and an inter-stage matching network formed between the driver amplifier and the output amplifier. The first semiconductor fabrication process is a lower voltage process and the second semiconductor fabrication process is a higher voltage process in one case. The use of the two different fabrication processes, and different voltage biases for the first semiconductor die and the second semiconductor die, leads to a number of advantages. The advantages include the simplification of one or more inter-stage matching networks in the power amplifier, increased radio frequency bandwidth, improved line-up efficiency among the stages of the power amplifier, greater overall efficiency, and reduced costs.

According to one aspect of the embodiments, an impedance transformation ratio between the driver amplifier and the output amplifier can be reduced to improve efficiency of the power amplifier device based on a selection of the first semiconductor fabrication process and the second semiconductor fabrication process. In another aspect, a gate width of the driver amplifier, which is formed using the first semiconductor fabrication process, can be increased to reduce the impedance transformation ratio as compared to using the second semiconductor fabrication process for the driver amplifier. In still another aspect, a power margin of the driver amplifier can be reduced to improve the line-up efficiency of the power amplifier device based on the selection and use of the first semiconductor fabrication process and the second semiconductor fabrication process.

In one example, the first semiconductor fabrication process includes a first Group III-V semiconductor technology process, and the second semiconductor fabrication process comprises a second, different Group III-V semiconductor technology process. More particularly, the first semiconductor fabrication process can include one of a Gallium Arsenide (GaAs) pseudomorphic high electron mobility transistor (PHEMT), GaAs heterojunction bipolar transistor (HBT), or complementary metal oxide semiconductor (CMOS) semiconductor manufacturing process. The second semiconductor fabrication process can include one of a gallium nitride (GaN) on silicon carbide (SiC), GaN on silicon (Si), or laterally-diffused metal-oxide semiconductor (LDMOS) semiconductor manufacturing process. Other semiconductor fabrication processes can be used in other cases.

In other aspects of the embodiments, the inter-stage matching network between the driver amplifier and the output amplifier can include at least one wire bond between the driver amplifier on the first semiconductor die and the output amplifier on the second semiconductor die. In one example case, the power amplifier device can be embodied as a Doherty amplifier, the output amplifier can include a main output and a peak output, and the at least one wire bond can include a number of wire bonds for the main output and a number of wire bonds for the peak output.

A first supply of power can be relied upon to provide a first voltage for the driver amplifier, and a second supply of power can be relied upon to provide a second voltage for the output amplifier, where the second voltage is greater than the first voltage. Thus, the driver amplifier can operate at a lower voltage and the output amplifier can operate at a higher voltage for line-up efficiency between the driver amplifier and the output amplifier.

### BRIEF DESCRIPTION OF THE DRAWINGS

Aspects of the present disclosure can be better understood with reference to the following drawings. It is noted that the elements in the drawings are not necessarily to scale, with emphasis instead being placed upon clearly illustrating the principles of the embodiments. In the drawings, like reference numerals designate like or corresponding, but not necessarily the same, elements throughout the several views.

FIG. 1 illustrates an example multi-stage power amplifier according various embodiments described herein.

FIGS. 2A and 2B illustrate example multi-stage power amplifier layouts according various embodiments described herein.

FIG. 3 illustrates another example multi-stage power amplifier according various embodiments described herein.

FIG. 4 illustrates interconnections between two semiconductor die for the multi-stage power amplifier shown in FIG. 3 according various embodiments described herein.

FIG. 5 illustrates representative power losses in the multi-stage power amplifiers shown in FIGS. 1 and 3 according various embodiments described herein.

### DETAILED DESCRIPTION

As noted above, the efficiency of a power amplifier, particularly a power amplifier for radio frequency (RF) signals, is driven by the intrinsic capability of the semiconductor materials used, the class and topology of the amplifier, the harmonic tuning of the amplifier, and other factors. In a cascaded power amplifier, one or more driver stages can provide an input signal to an output stage of the power amplifier. The final, output stage is typically the point of focus to improve the efficiency of power amplifiers. However, the driver stage can contribute significantly to the overall lack of efficiency of the power amplifier. The impact on the efficiency of the power amplifier attributed to the driver stage depends, in part, on the same factors discussed above, but also on the frequency band and the bandwidth of operation of the amplifier, among others.

New concepts for improved efficiency for multi-stage power amplifiers are described herein. The concepts can result in increased RF bandwidth, better line-up efficiency, and reduced power dissipation in multi-stage power amplifiers. In one example, a power amplifier includes a driver amplifier formed on a first semiconductor die using a first semiconductor fabrication process, an output amplifier formed on a second semiconductor die using a second semiconductor fabrication process, and an inter-stage matching network formed between the driver amplifier and the output amplifier. In one example, the first semiconductor fabrication process is a lower voltage process and the second semiconductor fabrication process is a higher voltage process. The use of the two different fabrication processes leads to a number of advantages, including the simplification of the inter-stage matching network, increased radio frequency bandwidth, improved line-up efficiency among the stages of the power amplifier, and lower cost, among others.

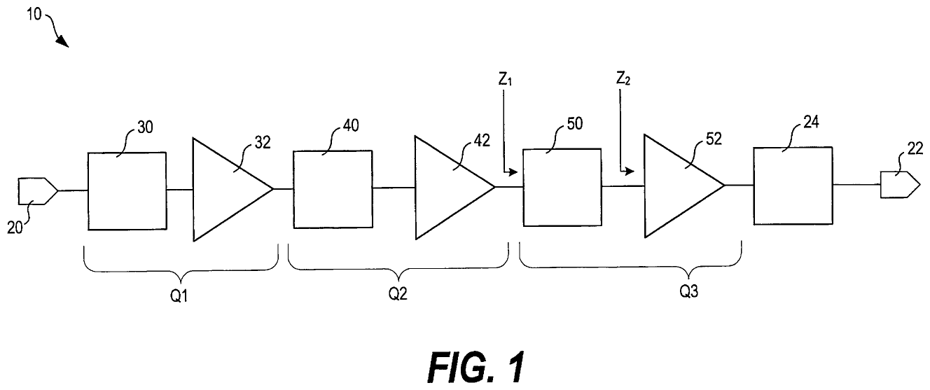

Turning to the drawings, FIG. 1 illustrates an example multi-stage power amplifier 10 according various embodiments described herein. The multi-stage power amplifier 10 includes an input 20, an output 22, an output matching network 24, and a number of amplifier stages Q1-Q3. The amplifier stage Q1 includes an input matching network 30 and an input amplifier 32. The amplifier stage Q2 includes a first inter-stage matching network 40 and a driver amplifier 42. The amplifier stage Q3 includes a second inter-stage matching network 50 and an output amplifier 52. The multi-stage power amplifier 10 is illustrated in FIG. 1 with three amplifier stages Q1-Q3 but can be implemented with additional or fewer amplifier stages.

The multi-stage power amplifier 10 can be designed for the amplification of an input signal provided to the input 20. The input signal can be an RF signal in the 3.0-5.0 Ghz range, for example, or other microwave frequency range. The input signal is amplified by each of the amplifier stages Q1-Q3, in turn. Among other design parameters, the operating bandwidth and efficiency of the multi-stage power amplifier 10 are of particular concern. The amplification provided by the multi-stage power amplifier 10 would ideally be linear (or as linear as possible) over the operating bandwidth with the highest efficiency possible.

The input amplifier 32 can be embodied as one or more power transistors. As examples, the input amplifier 32 can include power transistors arranged in a class AB amplifier configuration, a Doherty amplifier configuration, or another related configuration. Similarly, each of the driver amplifier 42 and the output amplifier 52 can be embodied as one or more power transistors. The driver amplifier 42 and the output amplifier 52 can include power transistors in a class AB amplifier configuration, a Doherty amplifier configuration, or another related configuration. Thus, the output of the output amplifier 52 can include a main output and a peak output, for example, as would be expected for Doherty amplifier configurations, although the concepts described herein can be applied to other amplifier configurations.

In the example shown in FIG. 1, the multi-stage power amplifier 10 can be formed using a relatively wide bandgap, high-power (e.g., between about 28-50 V) semiconductor fabrication process, such as gallium nitride (GaN) on silicon carbide (SiC), GaN on silicon (Si), or laterally-diffused metal-oxide semiconductor (LDMOS) semiconductor fabrication processes, among others. Thus, the input amplifier 32, driver amplifier 42, and output amplifier 52 can include power transistors formed using the GaN-on-SiC, GaN-on-Si, LDMOS, or related semiconductor fabrication processes. The amplifiers and the matching networks in the amplifier stages Q1-Q3 can be formed together on the same substrate or die using the same semiconductor manufacturing process and fabrication techniques. In other embodiments described below, the amplifier stages Q1 and Q2 can be formed using a different semiconductor fabrication process than the output amplifier 52, to achieve a number of different advantages described herein.

The input and output impedances of the multi-stage power amplifier 10 can be standard impedances, such as 50 Ohm impedances, for good power transfer to and from other circuit components. To the extent possible, the input matching network 30 is configured to transform the input impedance of the input amplifier 32 to a 50 Ohm input impedance of the multi-stage power amplifier 10, as seen at the input 20. Similarly, the first inter-stage matching network 40 is configured to match the output impedance of the input amplifier 32 to the input impedance of the driver amplifier 42, and the second inter-stage matching network 50 is configured to match the output impedance of the driver amplifier 42 to the input impedance of the output amplifier 52. Finally, the output matching network 24 is configured to transform the output impedance of the output amplifier 52 to a 50 Ohm output impedance of the multi-stage power amplifier 10, as seen at the output 22.

The input matching network 30, first inter-stage matching network 40, second inter-stage matching network 50, and output matching network 24 can be embodied, respectively, as networks of reactive components (e.g., “L” networks), including combinations of one or more capacitors and inductors. Ideally, the input matching network 30, first inter-stage matching network 40, second inter-stage matching network 50, and output matching network 24 would exhibit no resistivity to dissipate power. However, in practice, the capacitor and inductor networks are resistive, in part, and contribute to the loss of efficiency in the multi-stage power amplifier 10.

A number of physical and operational characteristics of the multi-stage power amplifier 10 are provided in Table 1. Particularly, Table 1 shows the gain in decibels (dB), loss in dB, power output (i.e., Pout) in decibel-milliwatts (dBm), power margin in dB, and gate width (i.e., Wg) in millimeter (mm) for the amplifier stages Q1-Q3. Table 1 also shows the loss and power output of the output matching network 24. The values of the physical and operational characteristics in Table 1 are provided by way of example, to provide background context for the concepts described herein.

TABLE 1

| | Output | | | |
|---|---|---|---|---|
| | Network | Q3 | Q2 | Q1 |
| Gain (dB) | | 16.00 | 19.00 | 19.00 |
| Loss (dB) | 0.30 | 6.00 | 9.00 | 9.00 |
| Pout (dBm) | 42.00 | 42.30 | 32.30 | 22.30 |
| Power Margin (dB) | | 0.10 | 4.10 | 8.10 |
| Wg (mm) | | 3.20 | 0.80 | 0.200 |
| Ids (A) | | 0.652 | 0.082 | 0.004 |

As shown in Table 1, the gate width of the input amplifier 32 is smaller than the gate width of driver amplifier 42, and the gate width of the driver amplifier 42 is smaller than the gate width of the output amplifier 52. Thus, the gate widths of the input amplifier 32, driver amplifier 42, and output amplifier 52 become progressively larger. Similarly, the output power of the amplifier stages Q1-Q3 become progressively larger, as does the amount of the current consumed by each amplifier stage Q1-Q3.

The power margin of the amplifier stage Q1 (i.e., 8.10 dB) is greater than the power margin of the amplifier stage Q2 (i.e., 4.10 dB), and the power margin of the amplifier stage Q2 is greater than the power margin of the amplifier stage Q3 (i.e., 0.10 dB). Thus, the amplifier stage Q1 is biased to operate further into the linear region of operation (i.e., with greater power margin for greater linearity and bandwidth), with more back-off from the saturation region at the expense of higher power dissipation. On the other hand, the amplifier stage Q3 is biased to operate in the linear region of operation but with relatively less back-off from the saturation region, to help reduce power dissipation in the amplifier stage Q3 (to the extent possible) at the expense of some linearity and bandwidth of the multi-stage power amplifier 10. In any case, the power margin of the amplifier stage Q3 is not closely aligned with the power margin of the amplifier stage Q2, and the power margin of the amplifier stage Q2 is not closely aligned with the power margin of the amplifier stage Q1. This line-up mismatch among the amplifier stages Q1-Q3 contributes to inefficiencies in the multi-stage power amplifier 10.

Table 1 also shows the losses of the amplifier stages Q1-Q3 and the output matching network 24, as well as the gain of the amplifier stages Q1-Q3. The efficiency of the multi-stage power amplifier 10 is driven by various factors, such as the intrinsic capability of the semiconductor materials used, the class and topology of the amplifier stages Q1-Q3, and the harmonic tuning of the amplifier stages Q1-Q3, among others.

A significant, but typically overlooked, aspect of the efficiency of the multi-stage power amplifier 10 can be attributed to power dissipation that occurs in matching networks. As mentioned above, ideal matching networks exhibit no resistivity and dissipate zero power. However, in practice, the input matching network 30, first inter-stage matching network 40, second inter-stage matching network 50, and output matching network 24 are partly resistive and dissipate power.

In the multi-stage power amplifier 10 shown in FIG. 1, the impedance transformation ratio between the driver amplifier 42 and the output amplifier 52 is particularly high. That is, the ratio of the input impedance Z₁ of the inter-stage matching network 50 and the input impedance Z₂ of the output amplifier 52 is high. There are a number of reasons for the high impedance transformation ratio, including the differences in the gate widths of the between the driver amplifier 42 and the output amplifier 52, which is due in part to the relatively high voltage used among all the amplifier stages Q1-Q3. In any case, a higher Z₁/Z₂ results in higher inter-stage power dissipation, lower overall efficiency, and a narrower bandwidth of the multi-stage power amplifier 10, as described in greater detail below. A lower Z₁/Z₂ results in lower inter-stage power dissipation, higher overall efficiency, and a wider bandwidth of the multi-stage power amplifier 10.

One reason for the relatively high Z₁/Z₂ in the multi-stage power amplifier 10 is the difference in the gate width between the driver amplifier 42 and the output amplifier 52. With the input amplifier 32, driver amplifier 42, and output amplifier 52 all operating at the same (or nearly the same) voltage, the gate width of the output amplifier 52 is about four times the size of the gate width of the driver amplifier 42. This relatively large difference in gate width contributes to the high Z₁/Z₂, because the second inter-stage matching network 50 depends on relatively large inductances to match the output impedance of the driver amplifier 42 with the input impedance of the output amplifier 52.

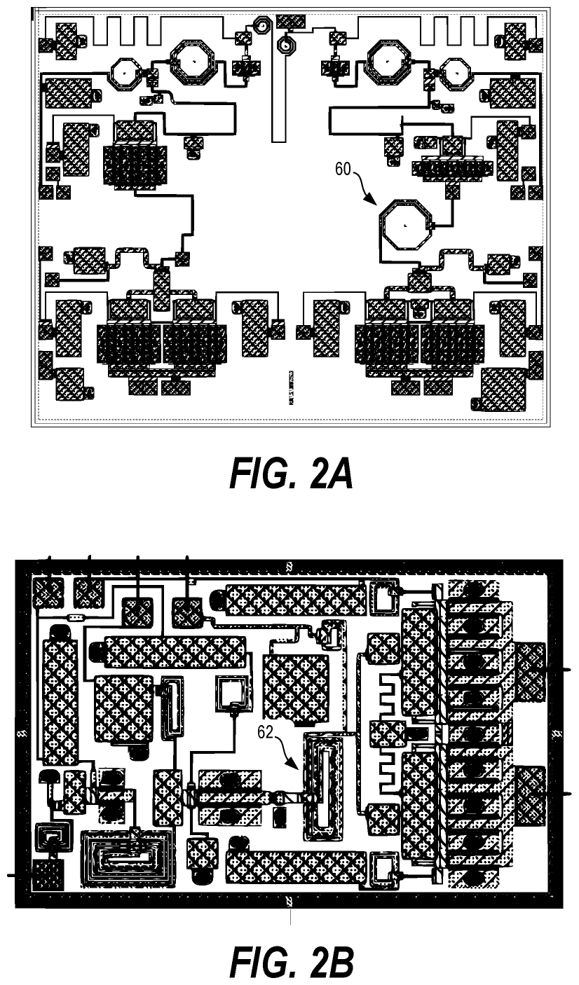

Large inductances can be formed for the second inter-stage matching network 50 using long metal traces. In that context, FIGS. 2A and 2B illustrate example layouts of multi-stage power amplifiers. In FIG. 2A, a metal trace 60 forms an inductance in an inter-stage matching network. Similarly, in FIG. 2B, a metal trace 62 forms an inductance in an inter-stage matching network. Both the metal trace 60 and the metal trace 62 are relatively long, exhibit resistance, and contribute to dissipation and inefficiency.

The width of the gate of the driver amplifier 42 could be increased to reduce the impedance transformation ratio between the driver amplifier 42 and the output amplifier 52. In that case, the size of the inductances in the second inter-stage matching network 50 could also be reduced. However, if the width of the gate of the driver amplifier 42 were increased, it would lead to an increase in the power margin of the driver amplifier 42. The difference between the power margin of the driver amplifier 42 and the power margin of the output amplifier 52 would be even greater in that case, resulting in even less line-up efficiency between the driver amplifier 42 and the output amplifier 52.

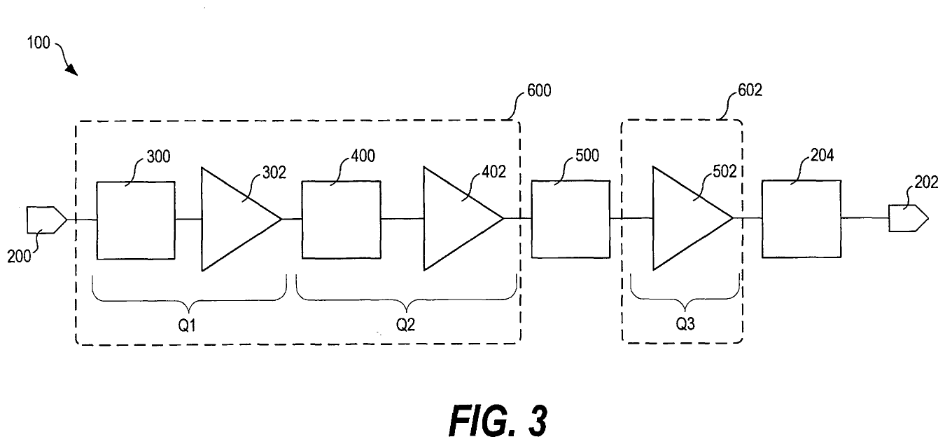

In view of the above-described efficiency problems of the multi-stage power amplifier 10, new concepts for improved efficiency for multi-stage power amplifiers are described herein. The concepts can result in increased RF bandwidth, better line-up efficiency, and reduced power dissipation in multi-stage power amplifiers, among other improvements. FIG. 3 illustrates another example multi-stage power amplifier 100 according various embodiments described herein. The multi-stage power amplifier 100 includes an input 200, an output 202, an output matching network 204, and a number of amplifier stages Q1-Q3. The amplifier stage Q1 includes an input matching network 300 and an input amplifier 302. The amplifier stage Q2 includes a first inter-stage matching network 400 and a driver amplifier 402. The amplifier stage Q3 includes an output amplifier 502. The multi-stage power amplifier 100 also includes a second inter-stage matching network 502 between driver amplifier 402 and the output amplifier 502. The multi-stage power amplifier 100 is illustrated in FIG. 3 with three amplifier stages Q1-Q3 but can be implemented with additional or fewer amplifier stages.

Similar to the multi-stage power amplifier 10 shown in FIG. 1, the multi-stage power amplifier 100 can be designed for the amplification of RF input signals in the 3.0-5.0 Ghz range, for example, or other microwave frequency ranges. The input amplifier 302 can be embodied as one or more power transistors. As examples, the input amplifier 302 can include power transistors arranged in a class AB amplifier configuration, a Doherty amplifier configuration, or another related configuration. Similarly, each of the driver amplifier 402 and the output amplifier 502 can be embodied as one or more power transistors. The driver amplifier 402 and the output amplifier 502 can include power transistors in a class AB amplifier configuration, a Doherty amplifier configuration, or another related configuration. Thus, the output of the output amplifier 502 can include a main output and a peak output, for example, as would be expected for Doherty amplifier configurations, although the concepts described herein can be applied to other amplifier configurations.

In FIG. 3, the output amplifier 502 can be formed using a different semiconductor fabrication process than the input amplifier 302 and the driver amplifier 402. In one example, the first and second amplifier stages Q1 and Q2 can be formed on a first semiconductor die 600 using a first Group III-V semiconductor fabrication process, and the third amplifier stage Q3 can be formed on a second semiconductor die 602 using a second Group III-V semiconductor fabrication process. The first semiconductor fabrication process can include a process for relatively low voltages, such as a Gallium Arsenide (GaAs) pseudomorphic high electron mobility transistor (PHEMT), GaAs heterojunction bipolar transistor (HBT), complementary metal oxide semiconductor (CMOS), or similar semiconductor fabrication process. The second semiconductor process can include a process for relatively high voltages, such as the GaN-on-SiC, GaN-on-Si, LDMOS, or related semiconductor fabrication process.

In the multi-stage power amplifier 100, the first and second amplifier stages Q1 and Q2 are operated at a relatively lower voltage (e.g., about 5V) suitable for the first semiconductor fabrication process, and the third amplifier stage Q3 is operated at a relatively higher voltage (e.g., about 40V) suitable for the second semiconductor fabrication process. In effect, the driver amplifier 402 is the “output amplifier” of the first semiconductor die 600, and the power margins of the input amplifier 302 and the driver amplifier 402 can be adjusted accordingly. Particularly, the driver amplifier 402 in FIG. 3 can be operated with less power margin (i.e., closer to saturation) for greater efficiency as compared to the driver amplifier 42 in FIG. 1. Thus, the multi-stage power amplifier 100 shown in FIG. 3 exhibits better line-up efficiency than the multi-stage power amplifier 100 shown in FIG. 1.

The width of the gate of the driver amplifier 402 can also be increased even when operating at the lower power margin. As a result of the increased width of the gate of the driver amplifier 402, the output impedance of the driver amplifier 402 is much closer to the input impedance of the output amplifier 502. This is in contrast to the larger difference between the output impedance of the driver amplifier 42 and the input impedance of the output amplifier 52 in FIG. 1. Thus, the transformation ratio between the driver amplifier 402 and the output amplifier 502 in FIG. 3 is reduced as compared to that between the driver amplifier 42 and the output amplifier 52 in FIG. 1.

The second inter-stage matching network 500 can be simplified in view of the relatively low transformation ratio between the driver amplifier 402 and the output amplifier 502. The inter-stage matching network 500 can be reduced significantly in some cases, with less need for larger inductance. The inductance of the inter-stage matching network 500 can even be realized using one or more wire bonds between the driver amplifier 402 on the first semiconductor die 600 and the output amplifier 502 on the second semiconductor die 602.

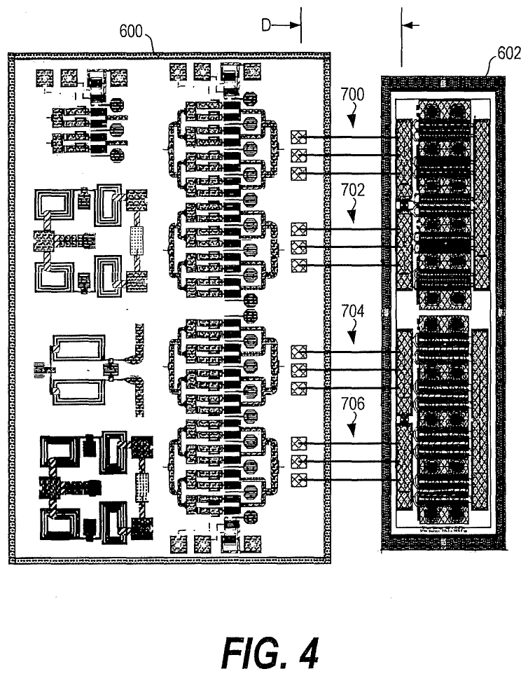

FIG. 4 illustrates interconnections between the semiconductor die 600 and the semiconductor die 602 for the multi-stage power amplifier 100 shown in FIG. 3. The semiconductor die 600 and the semiconductor die 602 can be encapsulated within the same semiconductor package, such as a quad flat no-lead (QFN), power quad flat no-lead (PQFN), or other suitable package. The illustration in FIG. 4 is provided as a representative example of certain connections between the semiconductor die 600 and the semiconductor die 602. FIG. 4 omits other electrical connections, details of the surrounding packaging for the multi-stage power amplifier 100, and other details for simplicity. For example, separate power, input, output, and other connections can be made to the semiconductor die 600 and the semiconductor die 602, but those connections are omitted for simplicity.

As shown in FIG. 4, groups of interconnections 700, 702, 704, and 706 are shown between the semiconductor die 600 and the semiconductor die 602. The interconnections 700 can include a number of bond wires that contact one or more bond pads on the semiconductor die 600 and extend to and contact one or more bond pads on the semiconductor die 602. The interconnections 702, 704, and 706 can, similarly, include a number of bond wires. Although three bond wires are shown for the interconnections 700, 702, 704, and 706 in FIG. 4, any suitable number of bond wires can be used.

In one example, the multi-stage power amplifier 100 can be embodied as a Doherty amplifier, and the interconnections 700 and 702 can be formed as part of the inter-stage matching network 500 between the driver amplifier 402 and the output amplifier 502 for the main output. The interconnections 704 and 706 can be formed as part of the inter-stage matching network 500 between the driver amplifier 402 and the output amplifier 502 for the peak output. Particularly, the interconnections 700, 702, 704, and 706 can form inductances in the inter-stage matching network 500, diminishing or eliminating the need for other, on-die inductances for the network, such as the metal trace 60 in FIG. 2A and the metal trace 62 in FIG. 2B. Additionally, although direct electrical connections are formed using the interconnections 700, 702, 704, and 706, the semiconductor die 600 and the semiconductor die 602 are not coupled through 50 Ohm matching networks, as would be conventionally used when interfacing between circuits on different chips.

The interconnections 700, 702, 704, and 706 can be embodied by bond wires formed from gold, copper, palladium, aluminum, silver, platinum, or other suitable material(s). The number, diameter, and loop form of the bond wires can be selected based on the current carrying capacity and the desired electrical characteristics of the bond wires, as formed. The number, diameter, and loop form of the bond wires will necessarily determine the amount of inductance exhibited by the interconnections 700, 702, 704, and 706. The loop form of the bond wires can be specified to achieve the desired amount of inductance. The loop form can be specified in terms of the diameter of the bond wires, the distance D between the bond pads, the maximum loop height of the bond wires from the bond pads, and other physical characteristics.

The interconnections 700, 702, 704, and 706 exhibit relatively little inductance as compared to other on-die inductances for matching networks, such as the metal trace 60 in FIG. 2A and the metal trace 62 in FIG. 2B. The lower inductances are suitable for the multi-stage power amplifier 100 because the transformation ratio between the driver amplifier 402 and the output amplifier 502 is relatively low. The interconnections 700, 702, 704, and 706 can also carry higher currents and exhibit relatively little resistance as compared to on-die inductances. Thus, the interconnections 700, 702, 704, and 706 dissipate less power and result in higher overall efficiency as compared to the use of on-die inductances.

Overall, the multi-stage power amplifier 100 shown in FIG. 3 exhibits a number of improvements over the multi-stage power amplifier 10 shown in FIG. 1. As described above, the selection of a first semiconductor fabrication process for the first semiconductor die 600 and a second, different semiconductor fabrication process for the second semiconductor die 602 can result in a reduced an impedance transformation ratio between the driver amplifier 402 and the output amplifier 502, improving the efficiency of the multi-stage power amplifier 100. With different voltages and semiconductor fabrication processes for the first semiconductor die 600 and the second semiconductor die 602, the gate width of the driver amplifier 402 can be increased, leading to a reduction in the impedance transformation ratio as compared to using the same voltage and semiconductor process for both the driver amplifier 402 and the output amplifier 502. The reduction in the impedance transformation ratio permits the use of bond wires, at least in part, for the second inter-stage matching network 500 between the first semiconductor die 600 and the second semiconductor die 602, which can also increase efficiency. Further, a power margin of the driver amplifier 402 can be reduced to improve line-up efficiency and RF bandwidth in the multi-stage power amplifier 100. Additionally, the first semiconductor fabrication process for the first semiconductor die 600 can be less costly, leading to a lower overall cost for the multi-stage power amplifier 100.

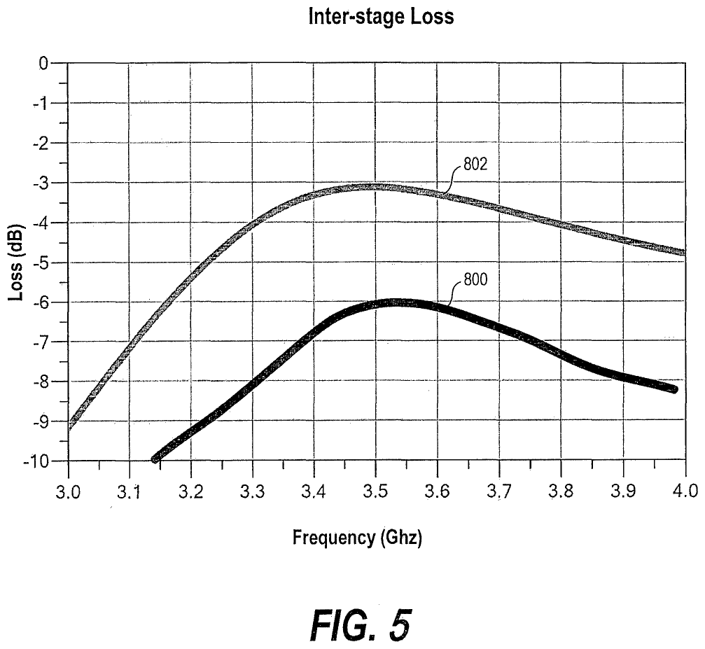

FIG. 5 illustrates representative power losses in the multi-stage power amplifiers 10 and 100 shown in FIGS. 1 and 3. In FIG. 5, the loss curve 800 is representative of the power loss, in dB and over frequency, of the amplifier stage Q3 of the multi-stage power amplifier 10 in FIG. 1. At about 3.5-3.6 Ghz, the power loss is the lowest, at about −6 dB. The loss curve 802 is representative of the power loss, in dB and over frequency, of the second inter-stage matching network 500 and the output amplifier 502 of the multi-stage power amplifier 100 in FIG. 3. At about 3.5-3.6 Ghz, the power loss is the lowest, at about −3 dB. The difference in power loss (i.e., from −6 dB to −3 dB) between the loss curves 800 and 802 can be attributed to the concepts described herein, including the efficiency gained through better line-up efficiency and reduced dissipation in inter-stage matching networks. The overall efficiency gains using the concepts described herein can range from about 3-6% for multi-stage power amplifiers, although other ranges of efficiency can be achieved depending on design factors.

In other embodiments, the multi-stage power amplifier 100 can be simulated on one or more computing devices. For example, one or more aspects of a semiconductor manufacturing process, such as the dopant distribution, the stress distribution, the device geometry, and other aspects of a manufacturing process to form the multi-stage power amplifier 100 can be simulated. Manufacturing process simulations can be relied upon to model the characteristics of the semiconductor devices (e.g., transistors) and other elements (e.g., resistors, inductors, capacitors, etc.) of the multi-stage power amplifier 100. One or more operational characteristics of the multi-stage power amplifier 100, such as the gain, power dissipation, gain-bandwidth, and other characteristics can also be simulated. Simulations can be relied upon to model the characteristics of the semiconductor devices (e.g., transistors) and other elements (e.g., resistors, inductors, capacitors, etc.) of the distributed amplifier 10. Thus, the distributed amplifier 10 can be simulated using one or more circuit simulator, semiconductor device modeling, semiconductor fabrication process simulation, or related Technology Computer Aided Design (TCAD) software tools.

In other embodiments, the multi-stage power amplifier 100 can be simulated on one or more computing devices. For example, one or more aspects of a semiconductor manufacturing process, such as the dopant distribution, the stress distribution, the device geometry, and other aspects of a manufacturing process to form the multi-stage power amplifier 100 can be simulated. Manufacturing process simulations can be relied upon to model the characteristics of the semiconductor devices (e.g., transistors) and other elements (e.g., resistors, inductors, capacitors, etc.) of the multi-stage power amplifier 100. One or more operational characteristics of the multi-stage power amplifier 100, such as the gain, power dissipation, gain-bandwidth, and other characteristics can also be simulated. Simulations can be relied upon to model the characteristics of the semiconductor devices (e.g., transistors) and other elements (e.g., resistors, inductors, capacitors, etc.) of the multi-stage power amplifier 100. Thus, the multi-stage power amplifier 100 can be simulated using one or more circuit simulator, semiconductor device modeling, semiconductor fabrication process simulation, or related TCAD software tools.

The multi-stage power amplifiers described herein, among others consistent with the concepts described herein, can be embodied in hardware or simulated as a number of circuit elements in software. Thus, a process for the evaluation of the multi-stage power amplifier 100 shown in FIG. 3 can include simulating the circuit elements of the multi-stage power amplifier 100 using one or more suitable TCAD simulation programs. Similarly, a process for the evaluation of the multi-stage power amplifier 100 shown in FIG. 3 can include simulating the circuit elements of the multi-stage power amplifier 100 using one or more suitable TCAD simulation programs.

If simulated in software, each circuit element can be embodied as a module or listing of code associated with certain parameters to simulate the element. The software to simulate the circuit elements can include program instructions embodied in the form of, for example, source code that includes human-readable statements written in a programming language or machine code that includes machine instructions recognizable by a suitable execution system, such as a processor in a computer system or other system. If embodied in hardware, each element can represent a circuit or a number of interconnected circuits.

One or more computing devices can execute the software to simulate the circuit elements that form the distributed amplifiers described herein, among others. The computing devices can include at least one processing circuit. Such a processing circuit can include, for example, one or more processors and one or more storage or memory devices coupled to a local interface. The local interface can include, for example, a data bus with an accompanying address/control bus or any other suitable bus structure.

The storage or memory devices can store data or components that are executable by the processors of the processing circuit. For example, data associated with one or more circuit elements of the distributed amplifiers can be stored in one or more storage devices and referenced for processing by one or more processors in the computing devices. Similarly, the software to simulate the circuit elements and/or other components can be stored in one or more storage devices and be executable by one or more processors in the computing devices.

Also, one or more or more of the components described herein that include software or program instructions can be embodied in any non-transitory computer-readable medium for use by or in connection with an instruction execution system such as, a processor in a computer system or other system. The computer-readable medium can contain, store, and/or maintain the software or program instructions for use by or in connection with the instruction execution system.

A computer-readable medium can include a physical media, such as, magnetic, optical, semiconductor, and/or other suitable media. Examples of a suitable computer-readable media include, but are not limited to, solid-state drives, magnetic drives, or flash memory. Further, any logic or component described herein can be implemented and structured in a variety of ways. For example, one or more components described can be implemented as modules or components of a single application. Further, one or more components described herein can be executed in one computing device or by using multiple computing devices.

Although embodiments have been described herein in detail, the descriptions are by way of example. The features of the embodiments described herein are representative and, in alternative embodiments, certain features and elements can be added or omitted. Additionally, modifications to aspects of the embodiments described herein can be made by those skilled in the art without departing from the spirit and scope of the present invention defined in the following claims, the scope of which are to be accorded the broadest interpretation so as to encompass modifications and equivalent structures.

1. A power amplifier device, comprising:
a driver amplifier formed on a first semiconductor die using a first semiconductor fabrication process;
an output amplifier formed on a second semiconductor die using a second semiconductor fabrication process; and
an inter-stage matching network formed between the driver amplifier on the first semiconductor die and the output amplifier on the second semiconductor die.

2. The power amplifier device of claim 1, wherein an impedance transformation ratio between the driver amplifier and the output amplifier is reduced to improve efficiency of the power amplifier device based on a selection of the first semiconductor fabrication process and the second semiconductor fabrication process.

3. The power amplifier device of claim 2, wherein a gate width of the driver amplifier formed using the first semiconductor fabrication process is increased to reduce the impedance transformation ratio as compared to using the second semiconductor fabrication process for the driver amplifier.

4. The power amplifier device of claim 1, wherein a power margin of the driver amplifier is reduced to improve efficiency of the power amplifier device based on a selection of the first semiconductor fabrication process and the second semiconductor fabrication process.

5. The power amplifier device of claim 1, wherein:
the first semiconductor fabrication process comprises a first Group 111-V semiconductor technology process; and
the second semiconductor fabrication process comprises a second Group 111-V semiconductor technology process.

6. The power amplifier device of claim 1, wherein:
the first semiconductor fabrication process comprises one of a Gallium Arsenide (GaAs) pseudomorphic high electron mobility transistor (PHEMT), GaAs heterojunction bipolar transistor (HBT), or complementary metal oxide semiconductor (CMOS) semiconductor manufacturing process; and
the second semiconductor fabrication process comprises one of a gallium nitride (GaN) on silicon carbide (SiC), GaN on silicon (Si), or laterally-diffused metal-oxide semiconductor (LDMOS) semiconductor manufacturing process.

7. The power amplifier device according to claim 1, further comprising:
an input amplifier formed on the first semiconductor die using the first semiconductor fabrication process; and
a second inter-stage matching network formed between the input amplifier and the driver amplifier on the first semiconductor die.

8. The power amplifier device according to claim 1, wherein the inter-stage matching network comprises at least one wire bond between the driver amplifier on the first semiconductor die and the output amplifier on the second semiconductor die.

9. The power amplifier device according to claim 1, wherein: the power amplifier device comprises a Doherty amplifier;
the output amplifier comprises a main output and a peak output; and
the inter-stage matching network comprises a first plurality of wire bonds for the main output and a second plurality of wire bonds for the peak output.

10. The power amplifier device of claim 1, further comprising:
a first supply of power at a first voltage for the driver amplifier; and
a second supply of power at a second voltage for the output amplifier, wherein the second voltage is greater than the first voltage.

11. The power amplifier device of claim 1, wherein the driver amplifier operates at a lower voltage and the output amplifier operates at a higher voltage for line-up efficiency between the driver amplifier and the output amplifier.

12. A power amplifier device, comprising:
an input amplifier formed on a first semiconductor die using a first semiconductor fabrication process;
a driver amplifier formed on the first semiconductor die using the first semiconductor fabrication process;
a first inter-stage matching network formed between the input amplifier and the driver amplifier on the first semiconductor die;
an output amplifier formed on a second semiconductor die using a second semiconductor fabrication process; and
a second inter-stage matching network comprising at least one wire bond between the driver amplifier on the first semiconductor die and the output amplifier on the second semiconductor die.

13. The power amplifier device of claim 12, wherein an impedance transformation ratio between the driver amplifier and the output amplifier is reduced to improve efficiency of the power amplifier device based on a selection of the first semiconductor fabrication process and the second semiconductor fabrication process.

14. The power amplifier device of claim 13, wherein a gate width of the driver amplifier formed using the first semiconductor fabrication process is increased to reduce the impedance transformation ratio as compared to using the second semiconductor fabrication process for the driver amplifier.

15. The power amplifier device of claim 12, wherein a power margin of the driver amplifier is reduced to improve efficiency of the power amplifier device based on a selection of the first semiconductor fabrication process and the second semiconductor fabrication process.

16. The power amplifier device of claim 12, wherein:
the first semiconductor fabrication process comprises a first Group 111-V semiconductor technology process; and
the second semiconductor fabrication process comprises a second Group III-V semiconductor technology process.

17. The power amplifier device of claim 12, wherein:
the first semiconductor fabrication process comprises one of a Gallium Arsenide (GaAs) pseudomorphic high electron mobility transistor (PHEMT), GaAs heterojunction bipolar transistor (HBT), or complementary metal oxide semiconductor (CMOS) semiconductor manufacturing process; and
the second semiconductor fabrication process comprises one of a gallium nitride (GaN) on silicon carbide (SiC), GaN on silicon (Si), or laterally-diffused metal-oxide semiconductor (LDMOS) semiconductor manufacturing process.

18. The power amplifier device of claim 12, wherein: the power amplifier device comprises a Doherty amplifier;
the output amplifier comprises a main output and a peak output; and
the second inter-stage matching network comprises a first plurality of wire bonds for the main output and a second plurality of wire bonds for the peak output.

19. The power amplifier device of claim 12, further comprising:
a first supply of power at a first voltage for the driver amplifier; and
a second supply of power at a second voltage for the output amplifier, wherein the second voltage is greater than the first voltage.

20. The power amplifier device of claim 12, wherein the driver amplifier operates at a lower voltage and the output amplifier operates at a higher voltage for line-up efficiency between the driver amplifier and the output amplifier.
